(19) United States
(12) Patent Application Publication
(10) Pub. No.: US 2025/0096803 A1
(43) Pub. Date: Mar. 20, 2025

(54) FORCE SENSOR APPARATUS AND KEYBOARD

(71) Applicant: Peratech IP Ltd, North Yorkshire (GB)

(72) Inventor: Fredrik Jonsson, Gävle (SE)

(73) Assignee: Peratech IP Ltd, North Yorkshire (GB)

(21) Appl. No.: 18/889,229

(22) Filed: Sep. 18, 2024

(30) Foreign Application Priority Data
Sep. 19, 2023 (GB) 2314307.6

(51) Int. Cl. H03K 17/96; G06F 3/02; G06F 3/023

(52) U.S. Cl. CPC H03K 17/9625; G06F 3/0202; G06F 3/023

(57) ABSTRACT

Examples disclosed relate to force sensing apparatus and methods of manufacture. A force sensing apparatus includes drive lines and sensing lines arranged to provide intersections, each of the intersections defining a sensel, wherein each sensel is configured to exhibit a variable resistance response in dependence on a magnitude of a force applied to the sensel. The sensels are grouped in multiple sensel groups and each of the sensels in a sensel group is configured to exhibit a variable resistance response within a group resistance range. The group resistance range of a first sensel group is different to the group resistance range of a further sensel group. The force sensing apparatus includes control modules, each of the control modules connected to a corresponding sensel group and configured to output a force signal indicative of a force applied to a sensel in the corresponding sensel group.

### TECHNICAL FIELD

The present disclosure relates to force sensing, in particular a force sensing apparatus configured to sense force applied to one or more keys of a keyboard. The present disclosure also relates to a keyboard and a method of manufacturing a force sensing keyboard.

### BACKGROUND

Force sensing technology can be used in electronic devices to allow an input device to be made to the electronic device which is dependent on the magnitude of the force applied to an input element, such as a key of a keyboard. For example, a light press on a key may cause a different input to a heavier press on the same key.

Such a “force enabled” keyboard may comprise a membrane having a matrix structure with keys positioned at intersections in the matrix. Variations in the keys can lead to variations in the force sensitivity of those keys. For example, different keycap sizes, shapes, and positions on the keyboard may cause the force response of those keys to vary. It can be challenging to achieve a uniform force sensitivity over a whole keyboard which employs force sensitive technology. Examples disclosed herein aim to solve problems in the art.

### BRIEF SUMMARY OF THE DISCLOSURE

Aspects and embodiments of the invention provide a force sensing apparatus, a keyboard, and a method of manufacturing a force sensing apparatus.

In accordance with the present disclosure there is provided a force sensing apparatus, comprising: a plurality of drive lines and a plurality of sensing lines arranged to provide a plurality of intersections, each of the plurality of intersections defining a sensel, wherein each sensel is configured to exhibit a variable resistance response in dependence on a magnitude of a force applied to the sensel; wherein the plurality of sensels are grouped in a plurality of sensel group; wherein each of the sensels in a sensel group is configured to exhibit a variable resistance response within a group resistance range; and wherein the group resistance range of a first sensel group of the plurality is different to the group resistance range of a further sensel group of the plurality; and a plurality of control modules, each of the plurality of control modules connected to a corresponding sensel group and configured to output a force signal indicative of a force applied to a sensel in the corresponding sensel group, wherein each of the plurality of control modules is tuned to operate in the group resistance range of the corresponding sensel group.

At least one of the plurality of sensel groups comprising a plurality of sensels.

The variable resistance response within the group resistance range may correspond to the force applied to the sensel within a force signal range of operation of the sensels in the sensel group. A first force signal range of the first sensel group may be different from a further force signal range of the further sensel group.

Each of the sensels in a sensel group may have a sensel size within a group sensel size range, thereby being configured to exhibit the variable resistance response within the group resistance range.

The force sensing apparatus may further comprise a plurality of keycaps. Each of the plurality of keycaps may be located adjacent a corresponding sensel of the plurality of sensels and may be configured to, when a force is applied to the keycap, exert a corresponding force on the adjacent corresponding sensel. In some examples a keycap may correspond to a plurality of sensels.

Each of the sensels in a sensel group may have a corresponding keycap having one or more of: a keycap size within a group keycap size range, and a keycap dome characteristic within a group keycap dome characteristic range; thereby being configured to exhibit the variable resistance response within the group resistance range.

At least two of the keycaps having corresponding sensels of a first sensel group may be separated, with at least one keycap having at least one corresponding sensel from a further sensel group positioned between the at least two keycaps having corresponding sensels of the first sensel group.

Each of the plurality of control modules may be configured to convert an analogue force sensel signal from a sensel in the corresponding sensel group to a digital output signal representative of the force signal indicative of a force applied to a sensel. Each of the plurality of control modules may comprise an analogue to digital converter configured to convert the analogue force sensel signal from a sensel in the corresponding sensel group to the digital output signal; the group resistance range of each of the plurality of control modules may correspond to the dynamic range of the analogue to digital converter.

Each of the plurality of control modules may be configured to provide a signal gain of a force sensel signal received from a sensel in the corresponding sensel group according to the group resistance range.

Each of the plurality of control modules may comprise: an input amplifier configured to receive the force sensel signal received from a sensel in the corresponding sensel group; and a gain resistor connected to the input amplifier, the gain resistor configured to provide signal gain. The input amplifier may be configured to operate over a particular range of resistance values, the control module comprising the gain resistor thereby having a signal range tuned to the group resistance range of the corresponding sensel group. The gain resistor may be configured to operate over a particular range of resistance values, the control module comprising the gain resistor thereby having a signal range tuned to the group resistance range of the corresponding sensel group.

Each of the plurality of control modules may comprise an offset resistor configured to limit an upper resistance limit of the group resistance range.

The input amplifier may comprise a transimpedance amplifier. The gain resistor may comprise a high resolution digital controlled resistor array.

The force sensing apparatus may comprise a resistive ink material located at the intersection between the drive line and the sensing line forming the sensel. The resistive ink material may comprise a resistive ink layer having a first face and a second opposing face, wherein the resistive ink layer is sandwiched between the plurality of drive lines at the first face and the plurality of sensing lines at the second face.

The number of sensels in a sensel group may be equal to the number of drive lines of that sensel group. Each sensel group may be associated with a dedicated sensing line connected to the dedicated control module for that sensel group. The total number of drive lines of the force sensing apparatus may be equal to the number of sensels in the sensel group having the largest number of sensels of all the sensel groups.

In an aspect there is provided a keyboard comprising any force sensing apparatus disclosed herein. The keyboard comprises a plurality of keycaps each associated with at least one corresponding sensel. The keyboard may comprise one or more sensel groups corresponding to: a plurality of alphabetic letter keys; a plurality of number keys; a plurality of keys of a numeric keypad region; a plurality of function keys; and a plurality of modifier keys.

In an aspect there is provided a method of manufacturing a force sensing apparatus, the method comprising: providing a plurality of drive lines; providing a plurality of sensing lines; arranging the plurality of drive lines and the plurality of sensing lines to provide a plurality of intersections, each of the plurality of intersections defining a sensel, wherein each sensel is configured to exhibit a variable resistance response in dependence on a magnitude of a force applied to the sensel; grouping the plurality of sensels into a plurality of sensel groups, wherein each of the sensels in a sensel group is configured to exhibit a variable resistance response within a group resistance range; and wherein the group resistance range of a first sensel group is different to the group resistance range of a further sensel group; providing a plurality of control modules; and connecting each of the plurality of control modules to a corresponding sensel group, wherein each of the plurality of control modules is tuned to operate in the group resistance range of the corresponding sensel group, and wherein each of the plurality of control modules is configured to output a force signal indicative of a force applied to a sensel in the corresponding sensel group.

### BRIEF DESCRIPTION OF THE DRAWINGS

Example embodiments are further described hereinafter with reference to the accompanying drawings, in which:

FIG. 1 shows an electronic device comprising a keyboard comprising a plurality of keys, according to examples disclosed herein;

FIG. 2 shows a plurality of drive lines and the plurality of sensing lines forming a force sensitive matrix, according to examples disclosed herein;

FIGS. 3a to 3c illustrate an example keyboard key layout, allocation of sensels to respective keys, and the sensels allocated to the keys;

FIGS. 4a to 4c illustrate an example keyboard key layout with a sensel group illustrated, the keyboard key layout with all keys allocated to a respective sensel group, and an indication of a portion of the sensels allocated to the grouped keys, according to examples disclosed herein;

FIG. 5 shows a schematic illustration of a force sensing apparatus according to examples disclosed herein;

FIG. 6 illustrates an example controller comprising three drive outputs and three sense inputs connected to respective sensel groups, according to examples disclosed herein;

FIG. 7a illustrates an example of resistance versus force for a typical sensel; and

FIG. 7b shows resistance vs force sensing ranges for a plurality of sensel groups according to examples disclosed herein; and

FIG. 8 illustrates an example method of manufacturing a manufacturing a force sensing apparatus according to examples disclosed herein.

### DETAILED DESCRIPTION

Force sensing technology can be used in electronic devices to allow an input device to be made to the electronic device which is dependent on the magnitude of the force applied to an input element, such as to a key of a keyboard. Such “force enabled” keyboards may comprise a membrane having a matrix structure with keys positioned at intersections in the matrix. Variations in the keys can lead to variations in the force sensitivity of those keys. For example, different keycap sizes, shapes, and positions on the keyboard may cause the force response of those keys to vary. It can be challenging to achieve a uniform force sensitivity over a whole keyboard which employs force sensitive technology due to such variations.

Traditional means of connecting the keyboard membrane of a force enabled keyboard to the output electronics can create challenges for the force measurement system, making it difficult to achieve a uniform force experience over a full force enabled keyboard (e.g., a force sensitive resistor (FSR) based membrane keyboard).

Examples disclosed herein aim to overcome this problem by dividing the membrane into sections such that FSR sensels (sensing elements e.g. located at matrix intersections of the membrane) that operate over a similar resistance range are grouped and connected to separate dedicated input channels of the overall measurement system. In this way, the measurement electronics for each sensel group can be tuned to the properties of the sensels (and keys) of that particular group. These solutions can be particularly useful in combination with measurement systems which employ transconductance amplifier input front ends, thereby allowing hardware tuning for both the upper and lower range of the input resistance range of each dedicated input channel. Other measurement systems such as those employing voltage divider inputs can also be used in combination with examples disclosed herein.

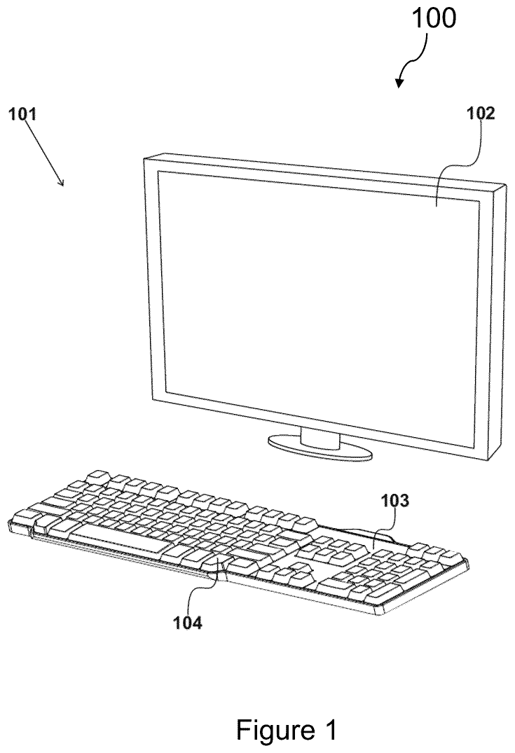

FIG. 1 illustrates an example electronic device 101 which is shown as a personal computer, comprising a keyboard 103 and a display 102. The keyboard 103 comprises a 20 plurality of keys 104 arranged to interact with a keyboard membrane. When a pressure, or force, is applied to a key 104 of the keyboard 103, an input is provided to the electronic device 101, for example to control an application running on the electronic device 101 or control some other functionality of the device 101. In a FSR based keyboard 103, a key may be pressed with different pressures/forces to provide a different input. Such a keyboard 103 may be used to control a gaming application, productivity application, or other application or software, for example.

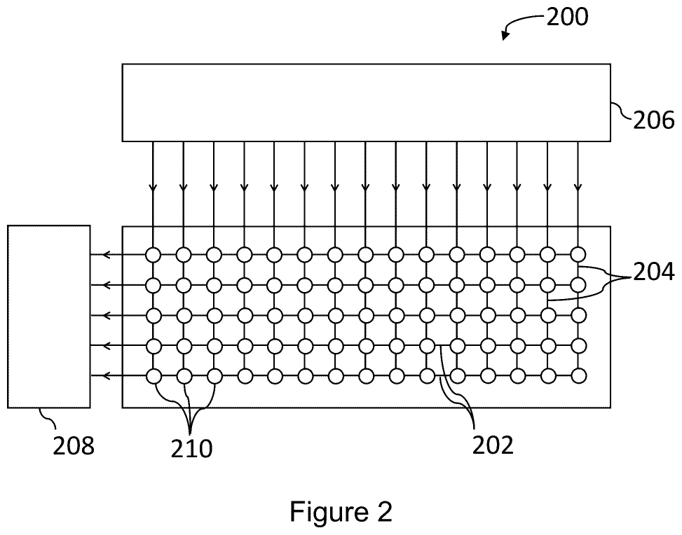

FIG. 2 shows an example sensing array 200 which can be used in a keyboard membrane. The sensing array 200 comprises a plurality of conductive rows 202 and a plurality of conductive columns 204. A driving control unit 206 is configured to provide the plurality of conductive columns 204, also known as drive lines, with a voltage sequentially to allow a current to flow through the drive lines 204. The sensing array 200 further comprises a sensing control unit 208 which is configured to receive an output from the plurality of conductive rows 202, also known as sensing lines. The output may be received in analogue form and converted into a digital output by means of an analogue-to-digital converter or similar as necessary.

In the example of FIG. 2, the sensing array 200 comprises a plurality of sensing elements 210 which are arranged at each intersection between the drive lines 204 and the sensing lines 202. Each sensing element 210 comprises a material which exhibits a variable resistance in response to an applied force. As each sensing element 210 is arranged to correspond with one the plurality of keys of a keyboard 103, when a force or pressure is applied to a key (and thus in turn to a corresponding sensing element 210), the electrical resistance of the sensing element 210 is reduced, and a current flows through the sensing element 210 and intersection for detection by the sensing control unit 208.

The sensing element may comprise a resistive ink, such as a quantum tunnelling material, e.g. such as that sold by the present applicant Peratech Holdco Limited under the trade mark QTC®.

In some examples, the rows 202 are arranged on an upper conductive layer and the columns 204 are arranged on a lower conductive layer respectively, with a sensing layer defining the sensing elements 210 applied to the rows and/or the columns located between the conductive layers. When a pressure is applied, the sensing layer 210 is brought into contact with the opposite conductive layer and compressed to reduce the resistance of the sensing layer. In this way, the resistance of each sensing element 210 is dependent on the applied force or area, such as the level of force applied to a key on keyboard 103.

Thus, in use, each drive line 204 may be driven by a driving control unit 206, and when a corresponding sensing element 210 is activated due to an applied force, a current flows through sensing line 204 to the sensing control unit 208. While the example 200 described may be used in a keyboard having a keyboard membrane, other examples may be used in other arrangements where there are a plurality of keys or sensing locations in a membrane.

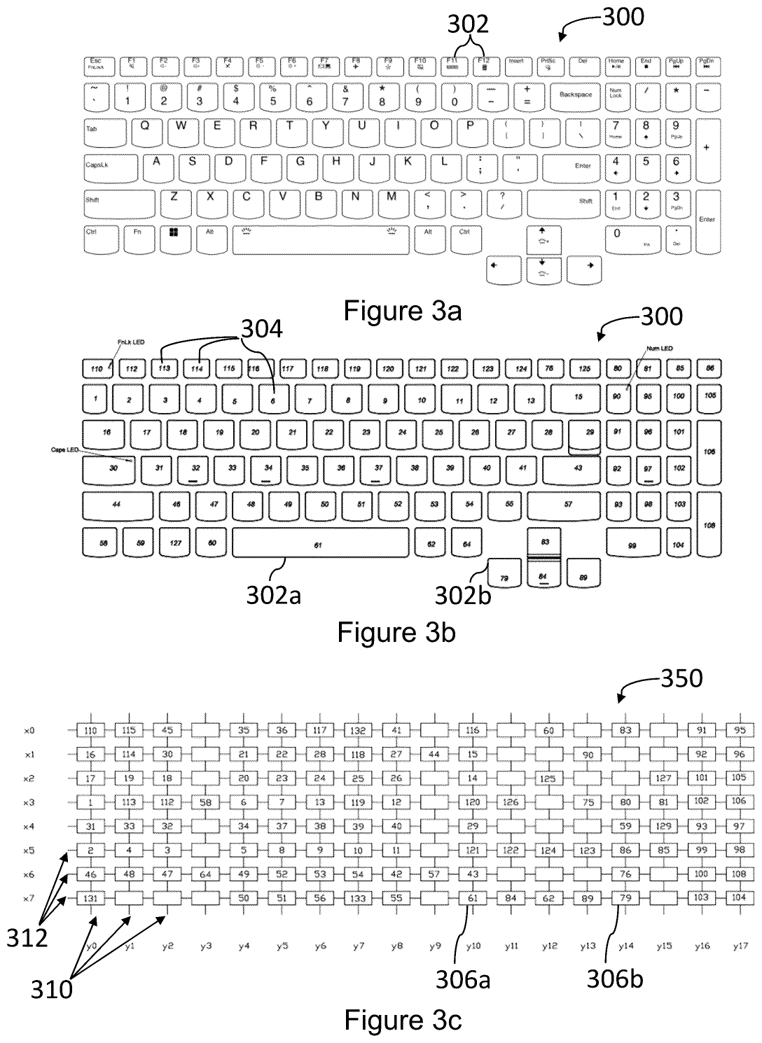

FIG. 3a illustrates an example of a layout of keys 302 (keycaps) on a keyboard 300. The illustrated example is a QWERTY keyboard 300 but other keyboards (e.g. a keyboard as stand-alone hardware, or as part of a laptop device or other portable electronics device), keypads (e.g. a numerical keypad, or specialised key arrays (e.g. as part of a security input device) may also be used in conjunction with the examples disclosed herein. FIG. 3b shows that each key 302 may have a unique key identifier 304, in this example a reference number. For example, the space bar key 302a has the reference number “61” in this example and the left arrow key 302b has the reference number “79”. FIG. 3b may be considered to show a key-sensel mapping for the keyboard because each unique key identifier 304 is associated with a dedicated sensel as shown in FIG. 3c.

FIG. 3c illustrates an example allocation of sensels of a force sensing matrix 350 (also called a force keyboard membrane 350, as shown in FIG. 2, to respective keys of the keyboard 300. In this example each key corresponds to a respective dedicated sensel. Each number in the matrix 350 corresponds to a particular key 302 in the keyboard layout 300. The sensel 306a for the space bar 302a, which is allocated unique key identifier “61”, and the sensel 306b for the left arrow key 302b, which is allocated unique key identifier “79”, are indicated.

In this example, every key 302 has a dedicated sensel 306, and a controller (not shown) of the keyboard 300 would connect to the matrix 350 using 18 drive outputs 310 (y0-y17) shown along the horizonal direction, and eight sense inputs 312 (x0-x7) shown along the vertical direction. The space bar sensel 306a is located at (x7, y10), and the left arrow key sensel 306b is located at (x7, y14), for example.

This force sensitive keyboard 300 may have problems due to different force responses of the keys 302. For example, the space bar 302a allocated to sensel 61 shares a controller input channel, namely sensing line x7, with the left arrow key allocated to sensel “79” on the same sensing line, x7. However, those two keys have much different FSR sensel responses due to the big differences in the sizes of the keycaps, and so having both of them connected to the same sensing line and therefore the same controller means the connected controller needs to operate over a relatively wide response range, to be able to process forces applied to (and thus in turn, resistance changes arising from pressing) both the larger space bar and the smaller left arrow key (and the other keys connected to the same sensing line 312). This means that resolution in force detection is reduced because the range of the control electronics needs to be able to receive a wide range of force inputs from the different keys on that sensing line.

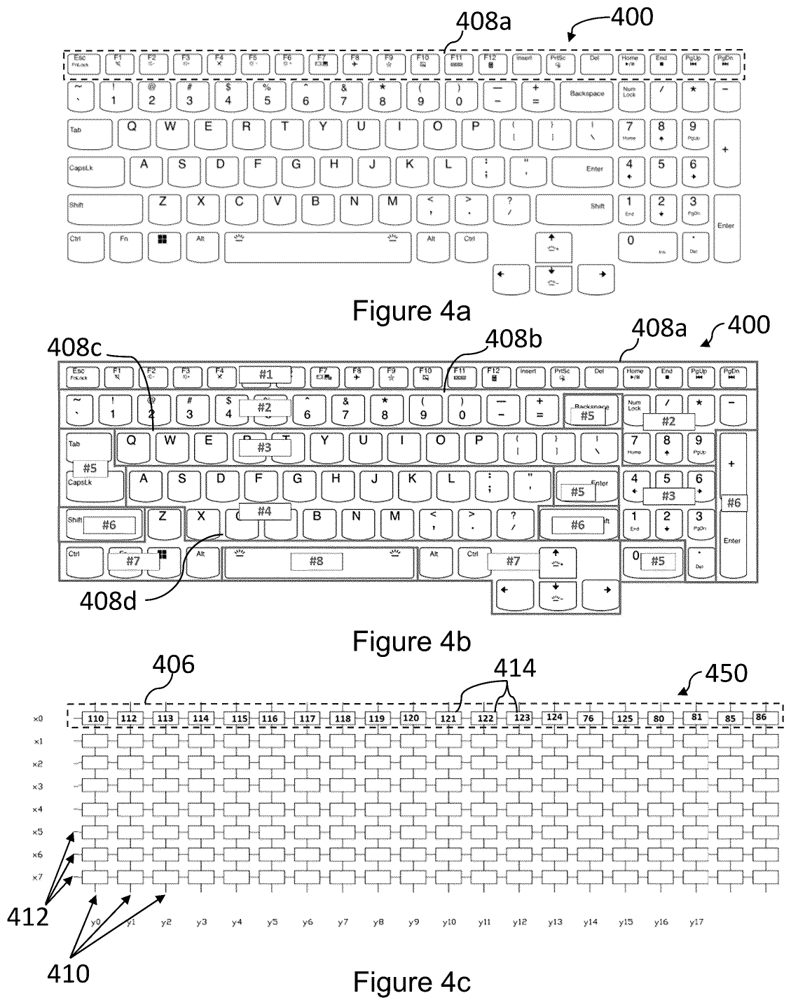

FIGS. 4a to 4c illustrate an example keyboard key layout 400 with a single key group 408a illustrated, the keyboard key layout 400 with all keys allocated to a respective key group 408a-d (or “segment”, corresponding to a sensel group), and an indication of a portion of the sensels 406 allocated to the grouped keys 408a of group 1. FIGS. 4a and 4b illustrate the keyboard 400 comprising any force sensing apparatus disclosed herein, and the keyboard 400 comprises a plurality of keycaps each associated with a corresponding sensel 414 as shown in FIG. 4c. In some examples a keycap may be associated with a plurality of sensels. Thus it can be considered that force sensing apparatuses disclosed herein may comprise a plurality of keycaps, and each of the plurality of keycaps is located adjacent a corresponding sensel of the plurality of sensels 414. Each of the plurality of keycaps is configured to, when a force is applied to the keycap, exert a corresponding force on the adjacent corresponding sensel.

FIG. 4a shows a layout of keys (keycaps) on a keyboard 400, and one group of keys is marked as a key group 408a. All the keys within that key group 408a have at least one corresponding sensel in a sensel group 406 of a connected FSR matrix or membrane as shown in FIG. 4c. That group of keys 408a is connected to a dedicated controller (not shown) which is configured to operate within the electronic parameters of the keys in that group. The keys are grouped such that they have comparable force sensing characteristics, and thus electronic parameters, so the connected controller can be tuned, or configured, to work particularly effectively for that key group. In this example, all the keys in the group have a similar size and key shape, and exhibit similar force response characteristics when pressed.

FIG. 4b shows an example of a plurality of key groups 408a-408d (in fact there are eight groups marked as #1 to #8 but not all are marked with a reference numeral 408a-d in FIG. 4b, for clarity). Every key on the keyboard 400 sits within one key group 408a-408d in this example. The keys are grouped according to them having similar force responses, for example because all the keys in a key group 408a-d have a similar keycap size. For example, for group #1 408a, this includes the function keys along the top of the keyboard which are all of a comparable size. Key group #5 includes the Tab, Caps, Backspace, Enter and numpad “0” keys and these are all of comparable size. The space bar is in a key group, group #8, of a single key, since there are no other keys of comparable size to the space bar. The space bar has a force response which is different to all the other keys on the keyboard 400, and so has a key group where it is the only key in the group. The keyboard 400 illustrated thus comprises sensel groups corresponding to a plurality of alphabetic letter keys; a plurality of number keys; a plurality of keys of a numeric keypad region; a plurality of function keys; and a plurality of modifier keys. In other examples a keyboard may comprise any one or more of such key types.

FIG. 4c illustrates an example allocation of sensels 414 in a sensel group 406, which corresponds to key group #1 408a. Each number in the matrix 450 corresponds to a particular key in group #1 408a of the keyboard layout 400. It will be appreciated that the keys in the other key groups #2 to #8 will also each have at least one corresponding sensel 414 in the matrix 450 but only those for key group #1 408a are shown here.

Each keycap group 408a-d contains keycaps with similar keycap sizes, which avoids a mixture of keycaps having different force sensitivities sharing the same sensing input line 412 of the controller. It may thus be said that each of the keycaps corresponding to sensels in a sensel group 406 (and thus in the corresponding key group 408a-d) may have a keycap size within a group keycap size range, thereby being configured to exhibit a variable resistance response within a group resistance range. The group resistance range may be considered to be the range of resistance, from a minimum resistance value to a maximum resistance value, which the keys in the relevant key group can provide when pressed.

In some examples, it may be the keycap dome characteristic which is accounted for in grouping keycaps together which have similar force responses. For example, cuboid-shaped keycaps may provide a different force response than a rounded-dome keycap, even if they are of a comparable size. Thus, each of the sensels in a sensel group may have a corresponding keycap having one or more of: a keycap size within a group keycap size range, and a keycap dome characteristic within a group keycap dome characteristic range; thereby being configured to exhibit the variable resistance response within the group resistance range.

In some examples, each of the sensels 414 in a sensel group 406 may have a sensel size within a group sensel size range, thereby being configured to exhibit the variable resistance response within the group resistance range. In some examples, each of the sensels 414 in a sensel group 406 may have a sensel size within a group sensel sensitivity range, thereby being configured to exhibit the variable resistance response within the group resistance range according to a particular sensitivity requirement. For example, a higher force resolution may be achieved for a particular group of sensels which can be grouped according to this particular sensing requirement (such as a group of sensels used for controlling a particular sensitive functionality, e.g. zoom in/zoom out, image processing parameter adjustment, precision movement of a controlled element such as a marker on a display screen or motion control of a remote device).

In this example, the largest number of keys in a key group is 20 (group #1 408a) so to accommodate this, an additional two drive lines 410, y18 and y19, are included so that there is a respective drive line 410 for each sensel 414 in a sensel group 406 in this example. Each sensel group 406 (for a corresponding key group 408a-d) in this example therefore has a corresponding number of drive lines 410 at least equal to the largest number of keys in a key group (and therefore the largest number of sensels 414 in a sensel group 406). Thus the number of sensels in a sensel group may be equal to the number of drive lines 410 of that sensel group. All the sensels 414 in the group 406 are connected to the same sense line 412 (x0 in this example) and control module of the sense line. In other words, each sensel group 406 may be associated with a dedicated sensing line 412 connected to the dedicated control module for that sensel group 406.

In different examples, the number of drive lines 410 and sensing lines 412 may be balanced, for example, to accommodate hardware costs, routing space available, scan speed, and the degree of segmentation (i.e. the number of key groups 408a-d) desired for a particular controller system. For example, rather than including additional drive lines to accommodate the number of sensels in a sensel group for connection to a single corresponding sense line as in FIG. 4c, there may be an additional sense line included so the group of e.g. 20 sensels is formed of two groups of e.g. 10 sensels and each of the two groups has a separate sensel line and associated control module (thereby adding a sense line to accommodate the group rather than two drive lines). Other combinations of drive/sense lines may be envisaged to accommodate the sensel groups.

FIG. 4a shows an example keyboard in which there is one sensel group comprising a plurality of sensels, and FIG. 4b shows an example keyboard in which there are a plurality of sensel groups each comprising a plurality of sensels. It will be appreciated that keyboards and force sensing apparatus may be envisaged within the scope of this disclosure which comprise different combinations of numbers of sensel groups comprising one or more sensels in the group(s) provided there is at least one sensel group comprising more than one sensel.

The variable resistance response within the group resistance range of a sensel group 406 may correspond to the force applied to the sensel 414 within a force signal range of operation of the sensels in the sensel group 406. For example, the sensels 414 in a sensel group 406 may detect a force sensitive signal between a range of 60 grams and 150 grams. A first force signal range of the first sensel group may be different from a further force signal range of the further sensel group. For example, the further force signal range of the further sensel group may be between a range of 90 grams and 180 grams. The respective force signal ranges of the plurality of sensel groups may partially overlap in some examples. The respective force signal ranges of the plurality of sensel groups may be distinct and not overlap in some examples.

In some examples, at least two of the keycaps having corresponding sensels of a first sensel group may be separated, with at least one keycap having at least one corresponding sensel from a further sensel group positioned between the at least two keycaps having corresponding sensels of the first sensel group. In the example of FIG. 4b, it can be seen that the left shift key in group #6 is physically separate from the right shift key which is also in group #6, and that letter keys from group #4 are located between these two keys in group #6. The keys in group #5 in this example are also physically separated from each other with keys allocated in other groups located between the group #5 keys. In other examples, as shown by e.g. the keys of groups #1 and #4 in FIG. 4b, the keys in a group may be physically located together without intervening keys from other groups between the keys of that group.

The force sensing apparatus 500 may comprise a resistive ink material located at the intersection between the drive line 410 and the sensing line 412 forming a sensel. There may therefore be such a resistive ink material located in a layer or series of intersection locations between a layer formed by the array of drive lines 410 and a layer formed by the array of sense lines 412, forming a sandwich structure with the resistive ink material between the two arrays of lines. That is, the resistive ink material may comprise a resistive ink layer having a first face and a second opposing face, wherein the resistive ink layer is sandwiched between the plurality of drive lines 410 at the first face and the plurality of sensing lines 412 at the second face.

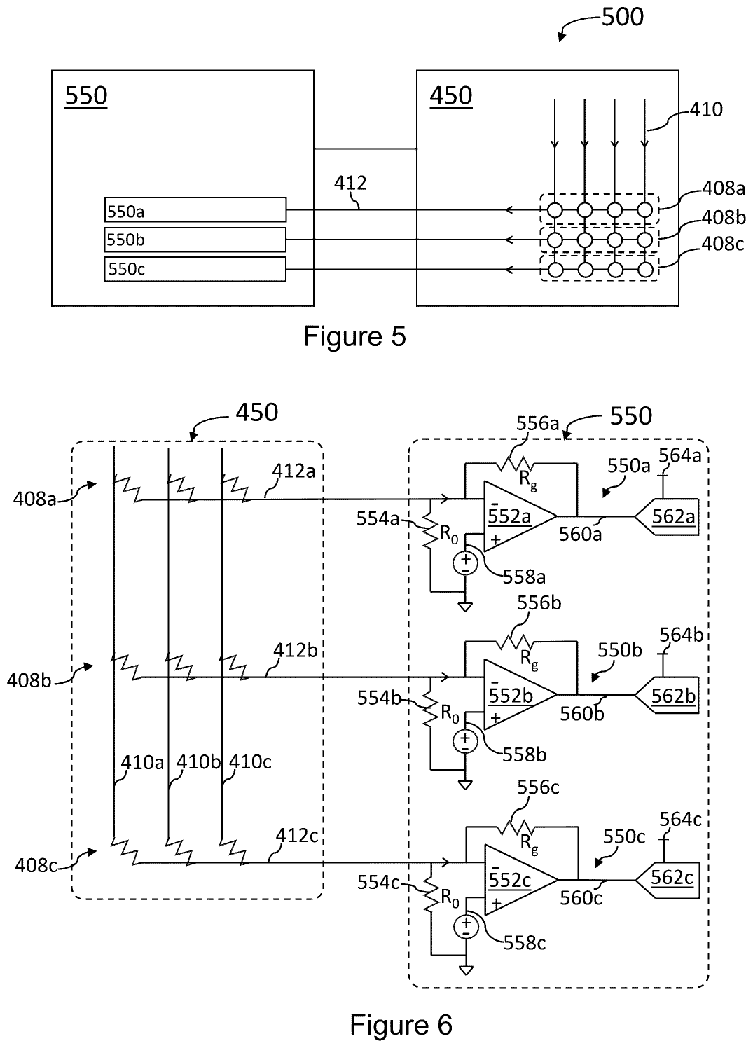

FIG. 4c may be considered to show a matrix portion 450 of a force sensing apparatus 500 as shown in FIG. 5. The matrix portion 450 comprises the plurality of drive lines 410 and the plurality of sensing lines 412 arranged to provide the plurality of intersections. Each of the plurality of intersections defines a sensel 414, wherein each sensel 414 is configured to exhibit a variable resistance response in dependence on a magnitude of a force applied to the sensel 414. The plurality of sensels 414 are grouped in a plurality of sensel groups 406, wherein each of the sensels 414 in a sensel group 406 is configured to exhibit a variable resistance response within a group resistance range. The group resistance range of a first sensel group 406 of the plurality is different to the group resistance range of a further sensel group of the plurality. The force sensing apparatus also comprises a plurality of control modules as described in relation to FIGS. 5 and 6.

FIG. 5 shows a force sensing apparatus 500 as disclosed herein. The force sensing matrix portion 450 of the force sensing apparatus 500 is as described in relation to FIGS. 4a-4c. Also shown is a plurality of control modules 550a-c. These may be part of a control circuit controller 550. Each of the plurality of control modules 550a-c is connected to a corresponding sensel group 408a-c in the force sensing matrix portion 450. Each of the plurality of control modules 550a-c is configured to output a force signal indicative of a force applied to a sensel in the corresponding sensel group 408a-c. Each of the plurality of control modules 550a-c is tuned to operate in the group resistance range of the corresponding sensel group 408a-c. The control modules 550a-c are described in more detail in relation to FIG. 6.

FIG. 6 illustrates an example controller 550 connected to a force sensing matrix 450 which comprises, for illustrative purposes, three drive output lines 410a-c and three sense input lines 412a-c connected to respective sensel groups 408a-c. Example features of the controller 550, which in this example comprises three control modules 550a-c, will now be described. FIG. 6 may be considered to illustrate a controller front end 550 having three drive output lines 410a-c and three sense input lines 412a-c.

Each control module 550a-c comprises an input from a sense line 412a-b of the FSR 450 which is connected to the negative input of an input amplifier 552a-c. The input amplifier 552a-c may comprise a transimpedance amplifier (TIA) 552a-c. The positive input of the input amplifier 552a-c is connected to a reference TREF+ 558a-c via a voltage source. As shown, each of the plurality of control modules 550a-c may comprise: an input amplifier 552a-c configured to receive the force sensel signal received from a sensel in the corresponding sensel group 408a-c; and a gain resistor R_{g} 556a-c connected to the input amplifier 552a-c. The gain resistor R_{g} 556a-c is configured to provide signal gain.

There is an offset resistor Rₒ 554a-c connected across the input from the sense line 412a-c and the TREF+ 558a-c. Thus, each of the plurality of control modules 550a-c may, as shown, comprise an offset resistor Rₒ 554a-c. The offset resistor Rₒ 554a-c may be configured to limit an upper resistance limit of the group resistance range.

There is a gain resistor R_{g} 556a-c connected across the input from the sense line 412a-c and the TIA output voltage VOUT 560a-c. Thus, each of the plurality of control modules 550a-c may be configured to provide a signal gain of a force sensel signal received from a sensel in the corresponding sensel group according to the group resistance range, for example by way of the gain resistors R_{g} 556a-c. The gain resistor R_{g} 556a-c may comprise a high resolution digital controlled resistor array in some examples.

Each TIA 552a-c output provides an output voltage VOUT 560a-c provided as input to an analogue to digital converter (ADC) 562a-c, which itself is connected to a reference voltage VREF+ 564a-c.

The force sensitive resistor (FSR) sensor resistance to voltage transformation through the input amplifiers 552a-c is given by the TIA resistance configurations, Rₒ 554a-c and R_{g} 556a-c, and the TREF+ 558a-c and the drive output voltage. The TIA 552a-c output voltage, VOUT 560a-c, is then further transformed to digital codes through the ADCs 562a-c and their reference configurations, VREF+ 564a-c. Each sense input has a dedicated separate offset resistor Rₒ 554a-c and gain resistor R_{g} 556a-c configuration allowing it to operate over different FSR sensor resistance ranges. The sensing membrane can therefore be arranged in such a way that similar key and FSR characteristics can be grouped together and connected to the same TIA 552a-c input.

In such an arrangement, each of the plurality of control modules 550a-c is configured to convert an analogue force sensel signal, from a sensing line 412a-c, from a sensel in the corresponding sensel group 408a-c, to a digital output signal representative of the force signal indicative of a force applied to a sensel. For example, as illustrated, each of the plurality of control modules may comprise an analogue to digital converter 562a-c configured to convert the analogue force sensel signal from a sensel in the corresponding sensel group 408a-c to the digital output signal. The group resistance range of each of the plurality of control modules 550a-c may correspond to the dynamic range of the analogue to digital converter 562a-c.

The input amplifier 552a-c may be configured to operate over a particular range of resistance values, and so the control modules 550a-c comprising the gain resistor R_{g} 556a-c thereby has a signal range tuned to the group resistance range of the corresponding sensel group. The gain resistor R_{g} 556a-c may be configured to operate over a particular range of resistance values, and so the control modules 550a-c comprising the gain resistor R_{g} 556a-c thereby has a signal range tuned to the group resistance range of the corresponding sensel group.

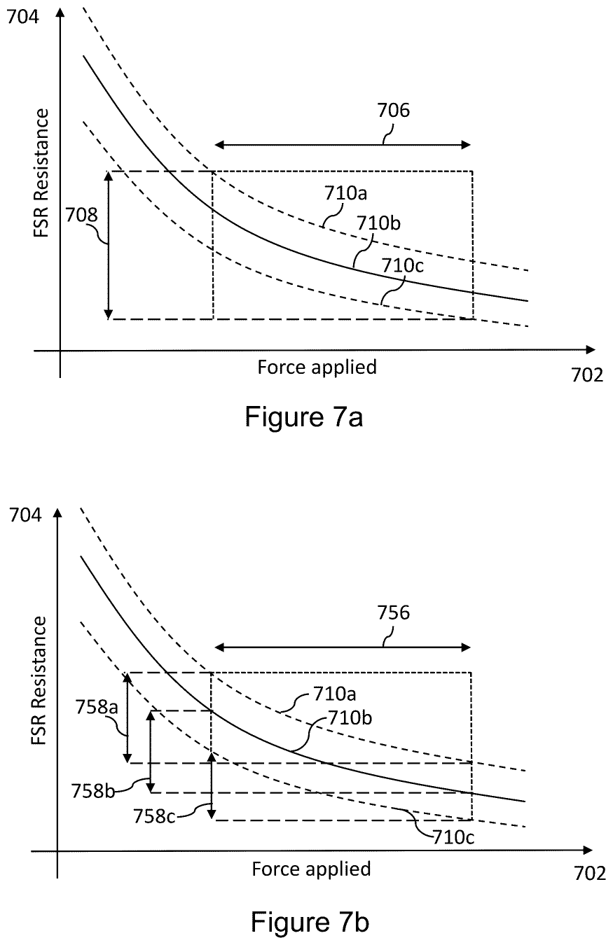

FIG. 7a illustrates an example of resistance versus force for a plurality of groups of sensels and an overall FSR resistance range is indicated for all the sensels in the groups. FIG. 7b shows resistance versus force sensing ranges (each sensel group has a corresponding group resistance range 758a-c) for a plurality of sensel groups according to examples disclosed herein. FIGS. 7a and 7b show applied force 702 along the horizontal axis plotted against FSR resistance 704 on the vertical axis.

Without any resistance range optimization as shown in FIG. 7a, the controller outputs FSR resistance data over the full resistance operation range 708 of the sensels. This operation range 708, for a circuit comprising an output ADC such as those shown in FIG. 6, may be called a non-optimised ADC range 708 and is large (and therefore low resolution, compared with the solutions described below).

However, in force enabled keyboard applications, the ADC range available to each sensel would in most cases not need to cover the full resistance range of all of the sensels present. The resistance may be limited to the FSR sensor activation threshold at dome collapse; for example this may be around 60 grams to 70 grams (when the key cap is just pressed down enough to be detected). The lower end resistance, at maximum applied force, can be given by the maximum force a user applies to the key, which is typically around 400 grams to 500 grams.

In FIG. 7a, this operation is illustrated with the ADC dynamic range 708 to detect force inputs to any key on the keyboard indicated along the FSR resistance axis 704, and the application range 706 (that is, the range of forces which the user is able to apply to the keys of the keyboard) indicated along the force axis 702. In this example there are three theoretical key group force-resistance curves 710a-c illustrated which, in examples with no key grouping (i.e. no sensel grouping) as discussed above, means that the ADC dynamic range 708 must be sufficient to cover all of the force responses possible for all of the key groups. The ADC dynamic range 708 in this example may be considered to be the range without key or sensel grouping (i.e. without keyboard segmentation).

In FIG. 7b, operation is illustrated with the ADC dynamic ranges 758a-c to detect force inputs to any key of a corresponding key group on the keyboard indicated along the FSR resistance axis 704, and the application range 756 corresponding to those key group (that is, the range of forces which the user is able to apply to the keys of that group of the keyboard) indicated along the force axis 702. In this example there are three theoretical key group force-resistance curves 710a-c illustrated. For example, the curve 710a may indicate the force response characteristics of group #1 indicated in FIG. 4b, the curve 710b may indicate the force response characteristics of group #2 indicated in FIG. 4b, and the curve 710c may indicate the force response characteristics of group #3 indicated in FIG. 4c. Of course this illustration is schematic and realistic force response curves for particular keys may differ dependent on the properties of the keys and sensels.

Since in this example there is a grouping of the keys in the key groups, with a dedicated control module tuned to the force response properties of the keys in each particular group, the ADC dynamic range 758a-c (i.e. the “group resistance range”) for each key group is individual (i.e. tuned) to the force responses possible for each of the separate key groups. Therefore it can be seen that the examples disclosed herein, whereby keys are grouped into key groups having similar force response characteristics, can be used to improve (i.e. increase) the ADC resolution obtained by tailoring the electrical properties of the ADC of the control module connected to a particular key group to the force response characteristics of keys in that key group. Each ADC need only operate over a smaller resistance range 758a-c for the connected sensel group, so the sensing resolution for that key group is increased.

Therefore, this approach can advantageously increase sensitivity to force inputs, by tuning the properties of the control module connected to a particular key group to the force response characteristics of keys in that group, which provide resistance values within a group resistance range for that group of keys. Furthermore, this approach may also advantageously reduce problems such as consistency of force response between different keys, and low response yield due to the control electronics not being optimised to keys providing smaller output signals when a force is applied to them. Therefore the user experience is improved. Furthermore, the examples disclosed herein allow for flexibility in mechanical integration and keycap sensor layouts therefore providing and improved force sensing apparatus which can be restriction in circuit and force sensing membrane design.

It will be appreciated that in discussions of key groups, the discussion also applies to the corresponding sensel groups, and in discussions of sensel groups, the discussion also applies to the corresponding key groups.

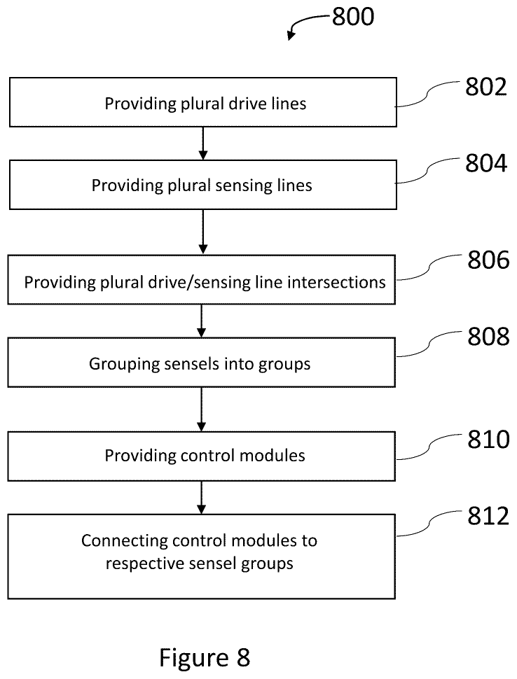

FIG. 8 illustrates an example method 800 of manufacturing a manufacturing a force sensing apparatus according to examples disclosed herein. The method 800 comprises: providing a plurality of drive lines 802; providing a plurality of sensing lines 804; arranging the plurality of drive lines and the plurality of sensing lines to provide a plurality of intersections 806, each of the plurality of intersections defining a sensel, wherein each sensel is configured to exhibit a variable resistance response in dependence on a magnitude of a force applied to the sensel; grouping the plurality of sensels into a plurality of sensel groups 808, wherein each of the sensels in a sensel group is configured to exhibit a variable resistance response within a group resistance range; and wherein the group resistance range of a first sensel group is different to the group resistance range of a further sensel group; providing a plurality of control modules 810; and connecting each of the plurality of control modules to a corresponding sensel group 812, wherein each of the plurality of control modules is tuned to operate in the group resistance range of the corresponding sensel group, and wherein each of the plurality of control modules is configured to output a force signal indicative of a force applied to a sensel in the corresponding sensel group.

The method may further comprise providing a plurality of keycaps; and locating each of the plurality of keycaps adjacent at least one corresponding sensel of the plurality of sensels such that when a force is applied to the keycap, a corresponding force is applied on the adjacent corresponding at least one sensel. The method may further comprise providing a housing; assembling the plurality of sensels and plurality of control modules within the housing; and locating the plurality of keycaps at a surface of the housing, to thereby form a keyboard apparatus such as keyboard 103, 400.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

It will be appreciated that various changes and modifications can be made to the present invention without departing from the scope of the present application.

1. A force sensing apparatus, comprising:
a plurality of drive lines and a plurality of sensing lines arranged to provide a plurality of intersections, each of the plurality of intersections defining a sensel, wherein each sensel is configured to exhibit a variable resistance response in dependence on a magnitude of a force applied to the sensel;
wherein the plurality of sensels are grouped in a plurality of sensel groups;
wherein each of the sensels in a sensel group is configured to exhibit a variable resistance response within a group resistance range; and
wherein the group resistance range of a first sensel group of the plurality is different to the group resistance range of a further sensel group of the plurality; and
a plurality of control modules, each of the plurality of control modules connected to a corresponding sensel group and configured to output a force signal indicative of a force applied to a sensel in the corresponding sensel group, wherein each of the plurality of control modules is tuned to operate in the group resistance range of the corresponding sensel group.

2. The force sensing apparatus claim 1, wherein the variable resistance response within the group resistance range corresponds to the force applied to the sensel within a force signal range of operation of the sensels in the sensel group.

3. The force sensing apparatus of claim 1, wherein the each of the sensels in a sensel group has a sensel size within a group sensel size range, thereby being configured to exhibit the variable resistance response within the group resistance range.

4. The force sensing apparatus of claim 1, further comprising a plurality of keycaps, wherein each of the plurality of keycaps is located adjacent a corresponding sensel of the plurality of sensels and is configured to, when a force is applied to the keycap, exert a corresponding force on the adjacent corresponding sensel.

5. The force sensing apparatus of claim 4, wherein each of the sensels in a sensel group has a corresponding keycap having one or more of:
a keycap size within a group keycap size range, and
a keycap dome characteristic within a group keycap dome characteristic range;
thereby being configured to exhibit the variable resistance response within the group resistance range.

6. The force sensing apparatus of claim 4, wherein at least two of the keycaps having corresponding sensels of a first sensel group are separated, with at least one keycap having at least one corresponding sensel from a further sensel group positioned between the at least two keycaps having corresponding sensels of the first sensel group.

7. The force sensing apparatus of claim 1, wherein each of the plurality of control modules is configured to convert an analogue force sensel signal from a sensel in the corresponding sensel group to a digital output signal representative of the force signal indicative of a force applied to a sensel.

8. The force sensing apparatus of claim 7, wherein each of the plurality of control modules comprise an analogue to digital converter configured to convert the analogue force sensel signal from a sensel in the corresponding sensel group to the digital output signal, and wherein the group resistance range of each of the plurality of control modules corresponds to the dynamic range of the analogue to digital converter.

9. The force sensing apparatus of claim 1, wherein each of the plurality of control modules is configured to provide a signal gain of a force sensel signal received from a sensel in the corresponding sensel group according to the group resistance range.

10. The force sensing apparatus of claim 1, wherein each of the plurality of control modules comprises:
an input amplifier configured to receive the force sensel signal received from a sensel in the corresponding sensel group; and
a gain resistor connected to the input amplifier, the gain resistor configured to provide signal gain.

11. The force sensing apparatus of claim 10, wherein one or more of:
the input amplifier is configured to operate over a particular range of resistance values, the control module comprising the gain resistor thereby having a signal range tuned to the group resistance range of the corresponding sensel group; and
the gain resistor is configured to operate over a particular range of resistance values, the control module comprising the gain resistor thereby having a signal range tuned to the group resistance range of the corresponding sensel group.

12. The force sensing apparatus of claim 1, wherein each of the plurality of control modules comprises an offset resistor configured to limit an upper resistance limit of the group resistance range.

13. The force sensing apparatus of claim 1, comprising a resistive ink material located at the intersection between the drive line and the sensing line forming the sensel.

14. The force sensing apparatus of claim 13, wherein the resistive ink material comprises a resistive ink layer having a first face and a second opposing face, wherein the resistive ink layer is sandwiched between the plurality of drive lines at the first face and the plurality of sensing lines at the second face.

15. The force sensing apparatus of claim 1, wherein the number of sensels in a sensel group is equal to the number of drive lines of that sensel group, and wherein each sensel group is associated with a dedicated sensing line connected to the dedicated control module for that sensel group.

16. A keyboard comprising the force sensing apparatus of claim 1, wherein the keyboard comprises a plurality of keycaps each associated with at least one corresponding sensel.

17. The keyboard of claim 16, wherein the keyboard comprises one or more sensel groups corresponding to:
a plurality of alphabetic letter keys;
a plurality of number keys;
a plurality of keys of a numeric keypad region;
a plurality of function keys; and
a plurality of modifier keys.

18. A method of manufacturing a force sensing apparatus, the method comprising:
providing a plurality of drive lines;
providing a plurality of sensing lines;
arranging the plurality of drive lines and the plurality of sensing lines to provide a plurality of intersections, each of the plurality of intersections defining a sensel, wherein each sensel is configured to exhibit a variable resistance response in dependence on a magnitude of a force applied to the sensel;
grouping the plurality of sensels into a plurality of sensel groups, wherein each of the sensels in a sensel group is configured to exhibit a variable resistance response within a group resistance range; and wherein the group resistance range of a first sensel group is different to the group resistance range of a further sensel group;
providing a plurality of control modules; and
connecting each of the plurality of control modules to a corresponding sensel group, wherein each of the plurality of control modules is tuned to operate in the group resistance range of the corresponding sensel group, and wherein each of the plurality of control modules is configured to output a force signal indicative of a force applied to a sensel in the corresponding sensel group.

19. The method of manufacturing a force sensing apparatus according to claim 18, further comprising:
providing a plurality of keycaps; and
locating each of the plurality of keycaps adjacent at least one corresponding sensel of the plurality of sensels such that when a force is applied to the keycap, a corresponding force is applied on the adjacent corresponding at least one sensel.

20. The method of manufacturing a force sensing apparatus according to claim 19, further comprising:
providing a housing;
assembling the plurality of sensels and plurality of control modules within the housing; and
locating the plurality of keycaps at a surface of the housing, to thereby form a keyboard apparatus.
